(19) United States
(12) Patent Application Publication
(10) Pub. No.: US 2022/0399351 A1
(43) Pub. Date: Dec. 15, 2022

(54) MULTI-BIT MEMORY DEVICE WITH NANOWIRE STRUCTURE

(71) Applicant: International Business Machines Corporation, Armonk, NY (US)

(72) Inventors: Lan Yu, Voorheesville, NY (US); Chun Wing Yeung, Portland, OR (US); Huai Huang, Clifton Park, NY (US); Robin Hsin Kuo CHAO, Portland, OR (US)

(21) Appl. No.: 17/348,113

(22) Filed: Jun. 15, 2021

(51) Int. Cl. H01L 27/1159; H01L 29/06; H01L 29/423; H01L 29/49; H01L 29/51; H01L 29/78; H01L 29/786; H01L 21/02; H01L 21/28; H01L 29/66

(52) U.S. Cl. CPC H01L 27/1159; H01L 29/0665; H01L 29/42392; H01L 29/4908; H01L 29/516; H01L 29/78391; H01L 29/78696; H01L 21/0259; H01L 29/40111; H01L 29/6684; H01L 29/66742

(57) ABSTRACT

An approach for utilizing an IC (integrated circuit) that is capable of storing multi-bit in storage is disclosed. The approach leverages the use of multiple nanowires structures as channels in a gate of a transistor. The use of multiple nanowires as channels allows for different Vₜ (i.e., voltage of device) to be dependent on the thickness of the fe (ferroelectric layer) that surrounds each of the nanowire channels. Memory window is about 2d (thickness of a fe layer). Setting voltage is also proportional to the fe layer thickness. The Vₜ of the device is the superposition of the various fe layers. For example, if there are three channels with three different Fe layer (of varying thickness), then four memory states can be achieved. More states can be achieved based on the number of channels in the device.

### BACKGROUND

The present invention relates generally semiconductor devices, and more particularly to utilizing nanowire to create multi-bit state for a memory cell.

The memory cell is foundation of a building block for computer memory. The memory cell is an electronic device that stores one or more bit of information. Typically, the memory commonly used are in binary (i.e., two bits of information) format. The binary bit can be represented by “ones” (i.e., high voltage) or “zeros” (i.e., low voltage) in a single memory cell. A memory cell typically consists of a single floating gate MOSFET (metal-oxide-semiconductor field-effect transistor) in an array of transistors.

However, multi-level cell is a memory cell that is capable of storing more than single bit of information. Recalled that a single memory cell from a single level cell can store one bit, multi-level cell can store two or even 5 bits of information per cell. Thus, multi-level cells has an advantage of reducing the number of MOSFETs required to store the same amount of data as single-level cells.

### SUMMARY

Aspects of the present invention disclose a device, computer-implemented method and a computer system for multi-bit cell storage in IC (integrated circuit) devices. The device includes, a substrate comprising one or more transistors; the one or more transistors comprises of one or more terminals, one or more source drain, one or more gates, one or more gate spacers, one or more channels and one or more channel layers; and the one or more channel layers envelopes the one or more channels, wherein: each of the one or more channel layers has a different thickness from each of the one or more channel layers, the different thickness of each of the one more channel layers contributes to an overall voltage of the multi-bit semiconductor device, the one or more channel layers comprises of a fe (ferroelectric) material.

The computer implemented method may be implemented by one or more computer processors and may include, forming one or more channels, one or more source/drain, one or more gates and one or more gate spacers on a substrate; depositing a first fe (ferroelectric) layer on the one or more channels; depositing a first OPL (organic planarization layer); chamfering the first fe layer; removing the first OPL; depositing a second fe layer; depositing a second OPL; recessing the second OPL; removing the second OPL; depositing the third fe layer; and filling one or more gates with a metal.

According to another embodiment of the present invention, there is provided a computer system. The computer system comprises a processing unit; and a memory coupled to the processing unit and storing instructions thereon. The instructions, when executed by the processing unit, perform acts of the method according to the embodiment of the present invention.

### BRIEF DESCRIPTION OF THE DRAWINGS

Preferred embodiments of the present invention will now be described, by way of example only, with reference to the following drawings, in which:

FIG. 1A is a depiction of a multi-bit memory device, designated as multi-bit FeRAM 101, in accordance with an embodiment of the present invention;

FIG. 1B illustrates four possible states (one for each bit) of multi-bit FeRAM 101, in accordance with an embodiment of the present invention;

FIG. 2 is a flowchart illustrating a process of forming multi-bit FeRAM 101, in accordance with an embodiment of the present invention;

FIGS. 3A-3B illustrates a process of forming the nanowires channels in a multi-bit FeRAM 101, in accordance with an embodiment of the present invention;

FIGS. 3C-3K illustrates a manufacturing view of forming multi-bit FeRAM 101, in accordance with an embodiment of the present invention; and

FIG. 4 depicts a block diagram, designated as 400, of components of a server computer capable of executing process 200, of FIG. 2, in accordance with an embodiment of the present invention.

### DETAILED DESCRIPTION

Current technology in IC memory devices (i.e., transistors) utilizes voltage fluctuation to store data as ones (high voltage) and zeros (i.e., low voltage). Recall that in a generic ferroelectric FET (feFET), a gate voltage can be defined as, V_{G}=φ_{S}+Q_{sc}(φₛ)/C_{stack}+E_{Fe}d_{Fe}, where Q^{sc} is the space charge in the silicon and C_{stack} is the capacitance of the series connection of ferroelectric and dielectric capacitor (assumption: no trapped or fixed charge). Furthermore, the memory window can be defined as MW=V_{FB+}−V_{FB-}≈2·E_{C}·d_{Fe}. The memory window depends on the coercive field and thickness of the material. Thus, two state currently exists in transistors.

Embodiments of the present invention provide an approach in utilizing a multi-bit cell storage on an IC (integrated circuit) over existing technology. The approach leverages the use of multiple nanowires structures as channels in a gate of a transistor. The use of multiple nanowires as channels allows for different Vₜ (i.e., voltage of device) to be dependent on the thickness of the fe (ferroelectric layer) that surrounds each of the nanowire channels. Memory window is about 2d (thickness of a fe layer). Setting voltage is also proportional to the fe layer thickness. The Vₜ of the device is the superposition of the various layers. For example, if there are three channels with three different fe layer (of varying thickness), then four memory states can be achieved. More states can be achieved based on the number of channels in the device.

The approach provides an advantage (in the use of multi-bit cell storage on a FeRAM) since it would be a great interest in the IC and AI chip industry with regards to co-integration of FeRAM with logic. A FeRAM (also known as FeRAM, F-RAM or FRAM) is a RAM (random-access memory) device that is similar in construction to DRAM (dynamic random access memory) but using a ferroelectric layer instead of a dielectric layer to achieve non-volatility. One advantage includes saving space by using the same transistor to store more than one bit. The approach of an embodiment of this invention can be implemented on (i) horizontal gate-all-around (GAA) devices that utilized horizontal nanowires including those devices used in memory application and (ii) devices including ferroelectric material, with varying the gate dielectric.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments, whether or not explicitly described.

It should be understood that the Figures are merely schematic and are not drawn to scale. It should also be understood that the same reference numerals are used throughout the Figures to indicate the same or similar parts.

Structural Features

However, specific to this disclosure, the use of FeRAM (Ferroelectric Random Access Memory) will be discussed with the pertaining to use of multi-bit cell storage. It is noted than other memory devices similar to FeRAM (e.g., horizontal GAA nanowire FETs) can be used to leverage the approach of the present invention. It is further noted that the term “nanosheet” and “nanowires” may be used interchangeably and is referring to the design/structure of the channels (between the source and drain).

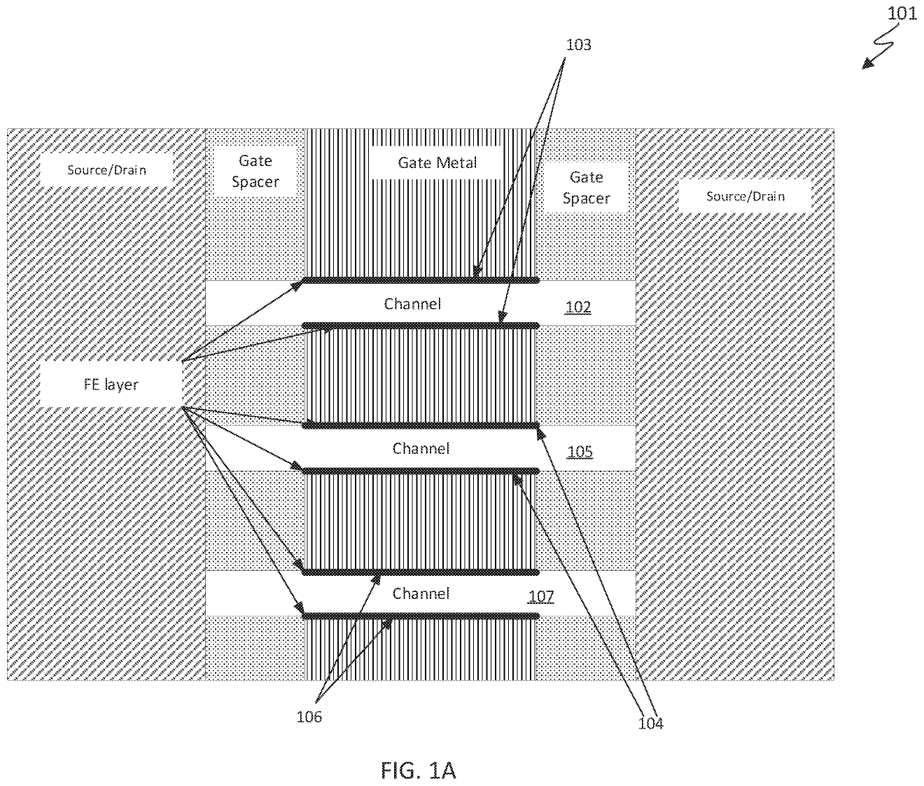

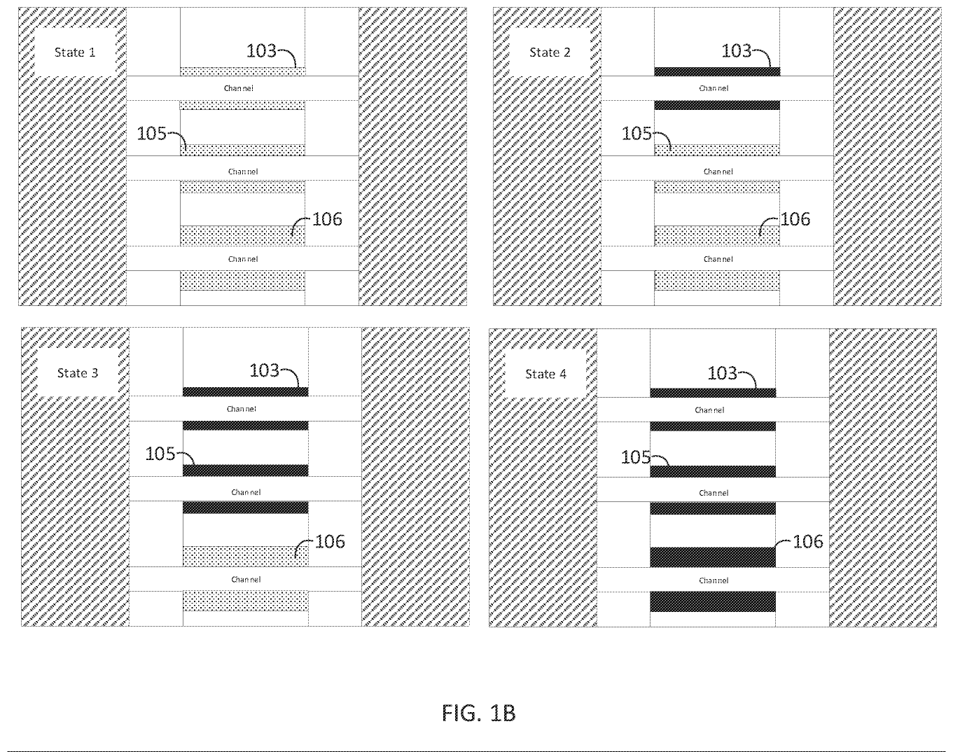

FIG. 1A is a depiction of an embodiment of the present invention, designated as multi-bit FeRAM 101.

The typical and generic FeRAM contains the following structures, such as a gate, fe (ferroelectric) layer, dielectric layer, one channel, source/drain and gate spacers. Multi-bit FeRAM 101, has similar components but utilizes multiple channels, made from nanowires and varying thickness of fe layers that surround the multiple channels.

In the depicted embodiment (i.e., multi-bit FeRAM 101 of FIG. 1), a four state FeRAM is shown. Multi-bit FeRAM 101 contains the following unique features: (i) first channel 102, (ii) second channel 105, (iii) third channel 107, (iv) first fe layer 103, (v) second fe layer 104 and (vi) third fe layer 106.

As previously stated, the three channels (e.g., 102, 105 and 107) are made from nanowires. These nanowires can have the diameter of approximately 8 nm, so that it can ensure a smooth OPL recess process during manufacturing. Any existing nanowires technology can be utilized including existing composition to create these three channels.

The three different fe (ferroelectric layer) layers that surrounds the three channels play a significant role in the present invention. The fe layers can be made from a high-k (dielectric constant) material such as HfO₂ (hafnium dioxide). The thickness of each layer cannot be the same. For example, the fe layer (i.e., 103) surrounding the first channel 102 has a thickness of T3, the fe layer (i.e., 104) surrounding the second channel 105 has a thickness equal to T2+T3 and the fe layer (i.e., 106) surrounding third channel 107 has a thickness equal to T1+T2+T3. The reasons for the varying thickness will be explained in the next section (i.e., FIG. 1B).

FIG. 1B illustrates four possible states (one for each bit) of multi-bit FeRAM 101, in accordance with an embodiment of the present invention. The voltage threshold (Vₜ) of the gate is determined by the device design. A Vₜ (of the device) is set by the HKMG (high-k/metal-gate) layer (e.g., HfO₂). Thus, based on the ranges of Vₜ of the device determines how many states can exist on a device. In the present embodiment, using a three-channel stack NS (nanosheet) FET, four states can be achieved (i.e., four different Vₜ). It is noted that more states can be achieved with more channel stacks.

Referring to FIG. 1B, state one, where there is no set state (i.e., Vₜ is at some designated voltage). In state two, first channel 102 is in “set state” wherein the fe layer (i.e., 103) surrounding that channel is “active” (i.e., Vₜ is at some designated voltage higher than the previous state's Vₜ). It is noted that “set” state in FIG. 1B is denoted by a darker/thicker line for their respective fe layers surround that particular channel. In state three, first channel 102 and second channel 105 is in “set state” and Vₜ is slightly higher than the state two's Vₜ. In state four, all three channels are in “set state” and Vₜ is slightly higher than the state three's Vₜ.

Process Features

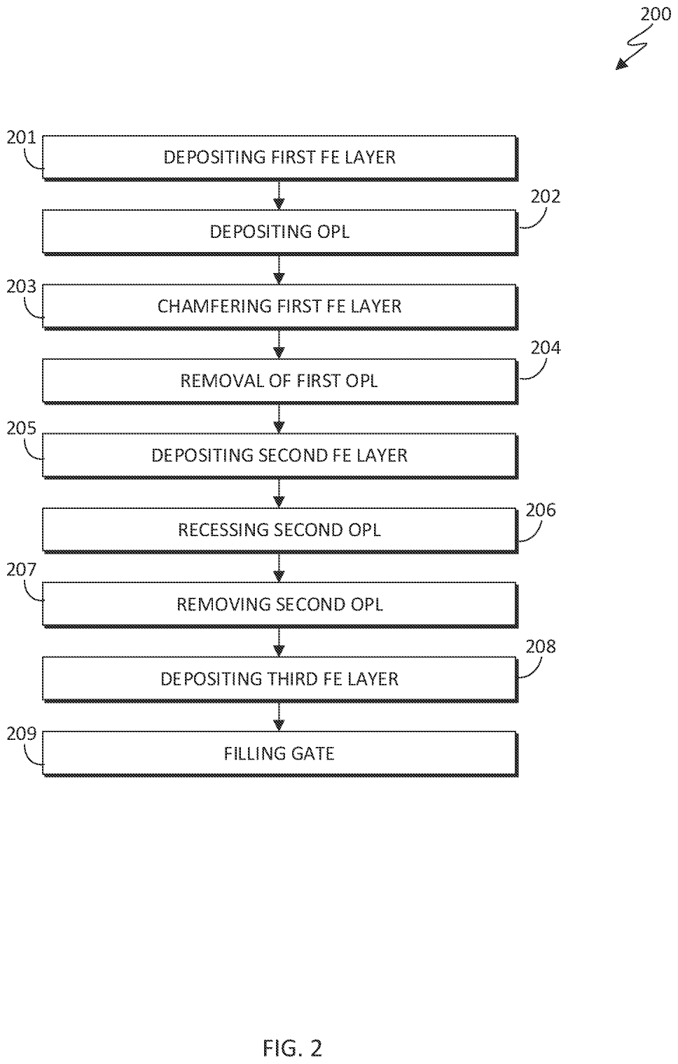

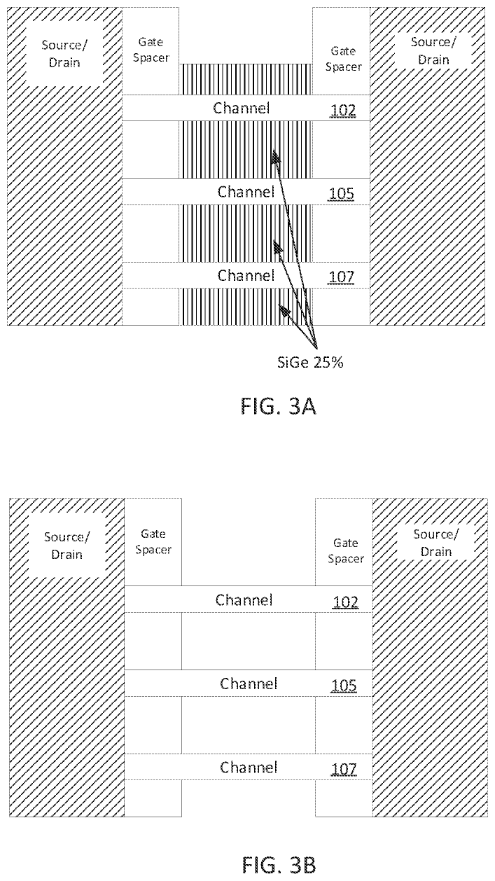

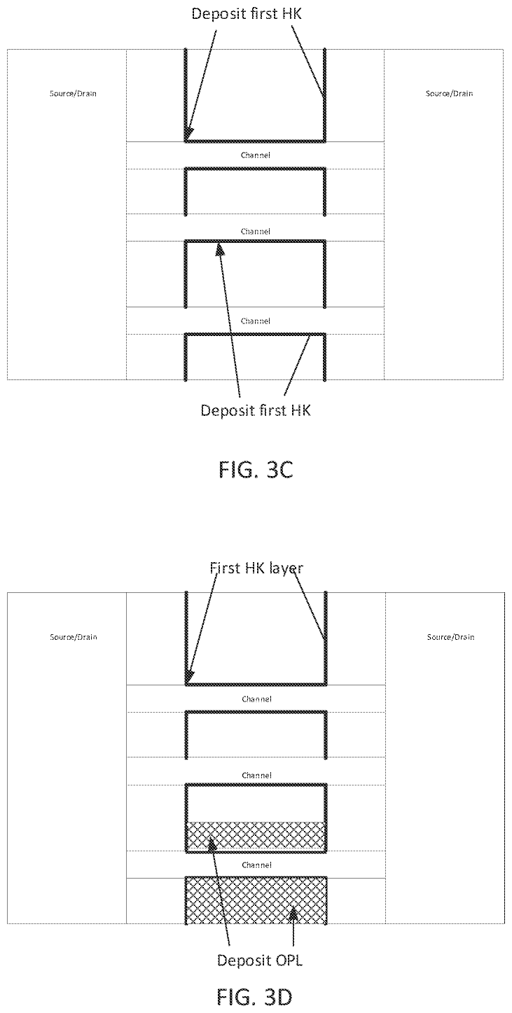

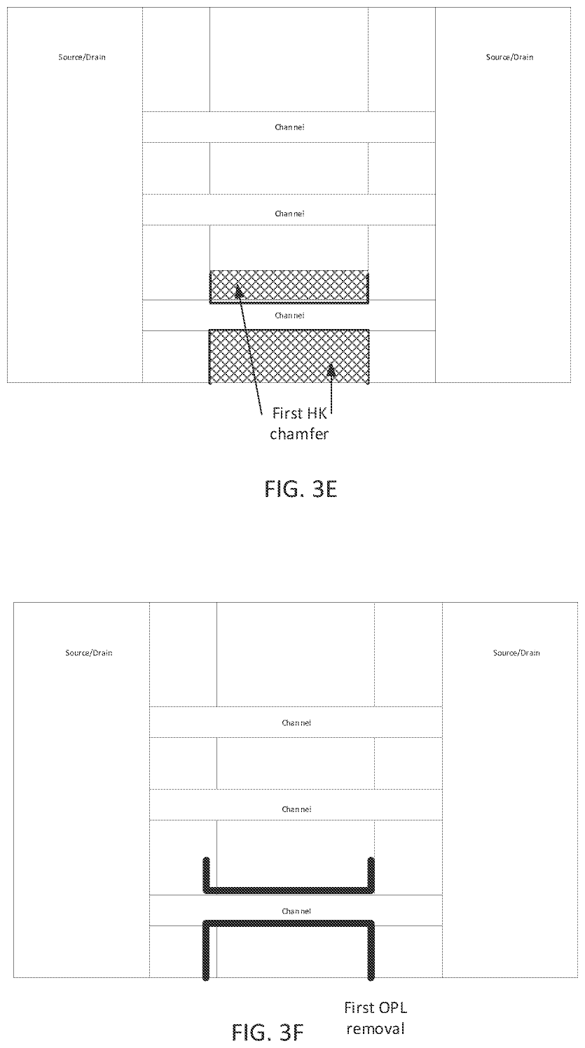

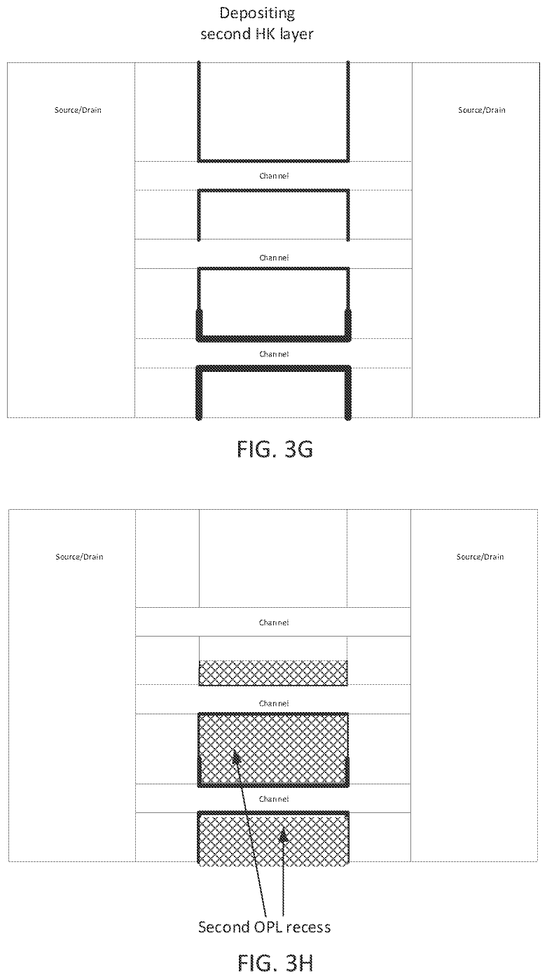

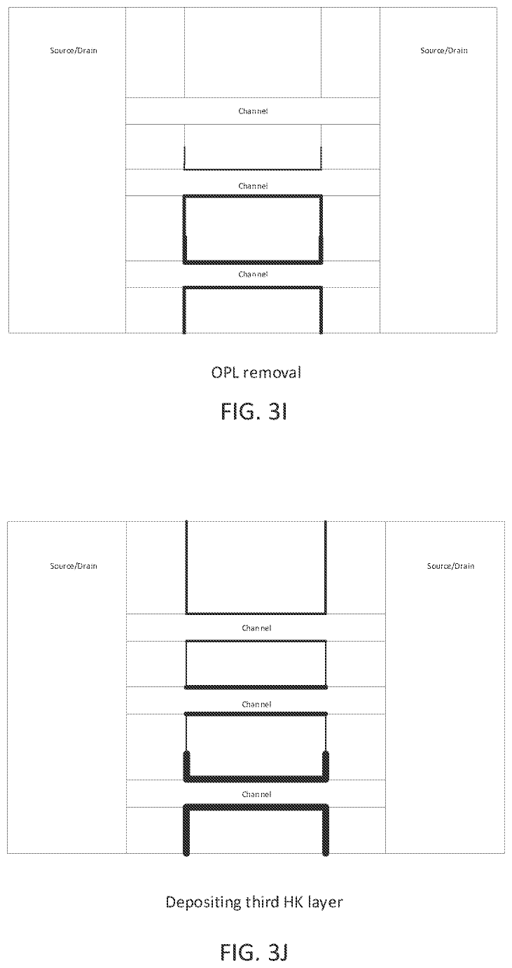

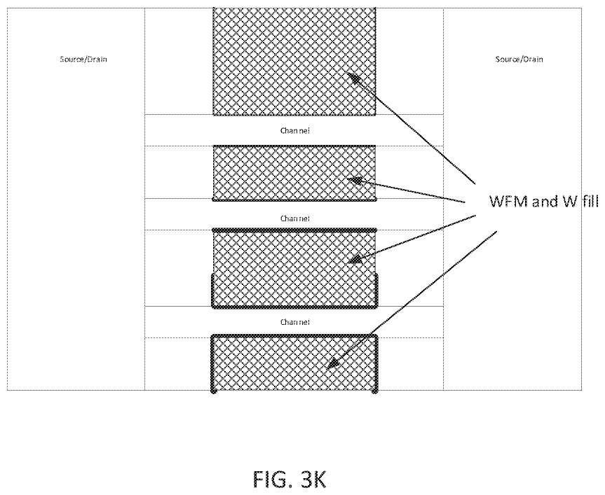

FIG. 2 is a flowchart, designated as process 200, illustrating a process of forming multi-bit FeRAM 101, in accordance with an embodiment of the present invention. It can be helpful to follow the steps by referring to FIGS. 3C-3K illustrates a manufacturing view of forming multi-bit FeRAM 101. In the present embodiment, process 200 is applied to a FeRAM. However, in other embodiments (not shown), it is noted than other memory devices (i.e., utilizing transistors with channels, gates, etc.) similar to FeRAM can be realized with process 200.

FIG. 3A-3B illustrates a process of forming the nanowires channels in a multi-bit FeRAM 101, in accordance with an embodiment of the present invention. There is an assumption that most of the components (e.g., source/drain, gate spacers, etc.) of a FET has already been formed using known/existing methods. This discussion will only pertain to creation of the stacks of channels (e.g., 102, 105 and 107). At FIG. 3A, EG removal process has begun and the three nanowires is formed. The gap (i.e., distance) between each nanowires can be large (i.e., 30 nm-50 nm or higher depending on the need). The diameter of the nanowires can be 8 nm. At 251, the SiGe 25% is removed (refer to FIG. 3B), exposing the three nanowire channels. It is noted that the nanowire diameter is relative small compared to the gap between the nanowires because the need for space/room to control the OPL recess. This will allow the OPL (organic planarization layer) recess to stop in the middle of the gap possible.

Now returning to process 200, at the beginning of the process a base structure (referring to FIG. 3B) already containing the nanowires channels are ready for the first step. The first step (step 201) involves depositing a first fe layer (i.e., thickness equal to T1), where the material for the fe can be made from a high k dielectric material (e.g., HfO₂, etc.) on to the three channels. The next step involves an OPL fill and recess (step 202). This step involves covering the bottom channel Fe layer, exposing the Fe layer on the other two higher channels.

Process 200 continues (step 203) with a first fe chamfer which means that the process is selectively removing the fe layers on the other two channels. Next step (step 204) includes a removal of the first OPL (i.e., removing the remaining OPL from the bottom channel). Process 200 continues with depositing a second fe layer (step 205). At this step, all three channels has a fe layer thickness equal to T2 and the fe layer on the bottom channel is equal to T2+T1.

Next step (step 206) involves a second OPL recess and second fe chamfer (i.e., selective removal of fe layers on other channels). Essentially step 206 is covering the middle and bottom channel fe layer and exposing the top channel fe layer.

Process 200 continues with OPL removal (step 207). This step removes the remaining OPL from the top channel. The next step (step 208) deposits another layer of fe. The thickness of the fe layer on the top channel can be designated as T3.

The final step (step 209) of process 200 includes filling the gate. For example, the gate can be filled with WFM (work function metal) and W (Tugsten). At this point, the final structure has three channels of varying thickness (i.e. Fe layers). For example, the thickness of the fe layer on the top channel is equal to T3, middle Fe layer thickness is equal to T2+T3 and the thickness of the bottom Fe layer is equal to T1+T2+T3.

FIGS. 3C-3K illustrates a manufacturing view of forming multi-bit FeRAM 101, in accordance with an embodiment of the present invention.

FIG. 3C illustrate depositing the first HK layer. FIG. 3D illustrates depositing an OPL and recessing the fe layers from the two channels. FIG. 3E illustrates a first fe chamfer by selectively removing the fe layers on the other two channels. FIG. 3F illustrate a removal of the first OPL (i.e., removing the remaining OPL from the bottom channel). FIG. 3G illustrates depositing a second fe layer. FIG. 3H illustrates a second OPL recess and fe chamfer (i.e., selective removal of Fe layers on other channels). FIG. 3I illustrates a second OPL removal. FIG. 3J illustrates depositing another layer of fe. FIG. 3K illustrates WFM and W (Tugsten) fill of the gate.

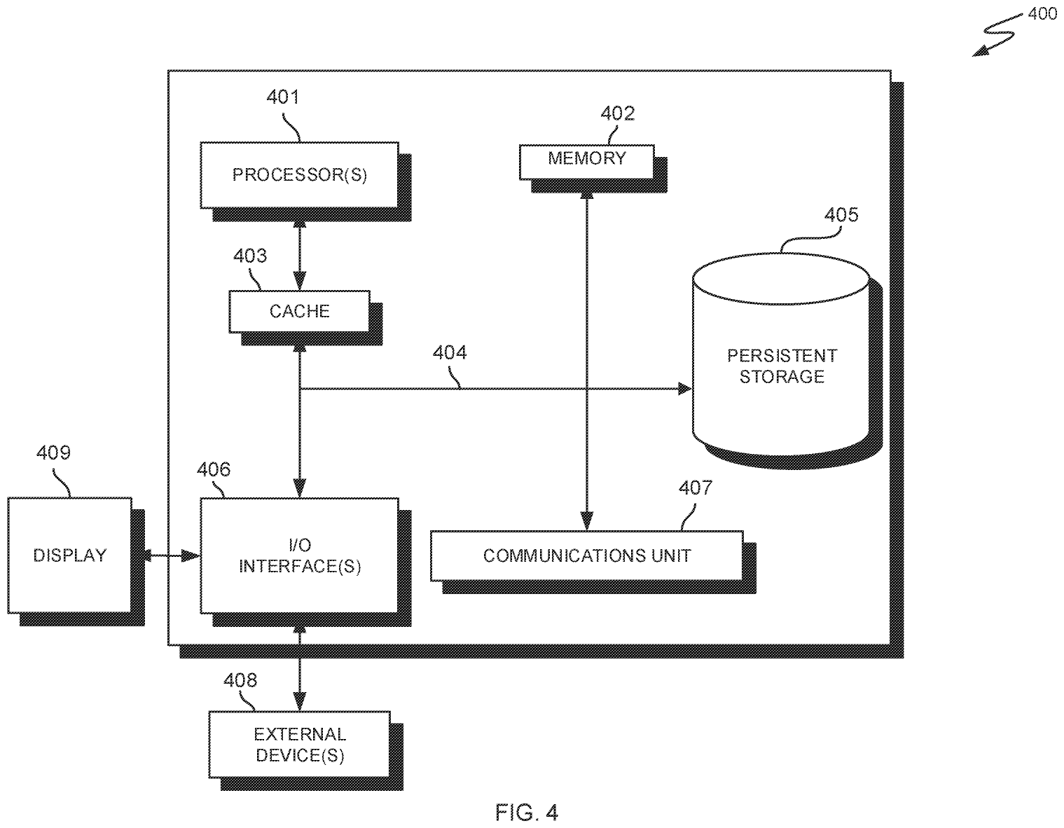

FIG. 4, designated as 400, depicts a block diagram of components of a computer system executing process 220, in accordance with an illustrative embodiment of the present invention. It should be appreciated that FIG. 4 provides only an illustration of one implementation and does not imply any limitations with regard to the environments in which different embodiments may be implemented. Many modifications to the depicted environment may be made.

FIG. 4 includes processor(s) 401, cache 403, memory 402, persistent storage 405, communications unit 407, input/output (I/O) interface(s) 406, and communications fabric 404. Communications fabric 404 provides communications between cache 403, memory 402, persistent storage 405, communications unit 407, and input/output (I/O) interface(s) 406. Communications fabric 404 can be implemented with any architecture designed for passing data and/or control information between processors (such as microprocessors, communications and network processors, etc.), system memory, peripheral devices, and any other hardware components within a system. For example, communications fabric 404 can be implemented with one or more buses or a crossbar switch.

Memory 402 and persistent storage 405 are computer readable storage media. In this embodiment, memory 402 includes random access memory (RAM). In general, memory 402 can include any suitable volatile or non-volatile computer readable storage media. Cache 403 is a fast memory that enhances the performance of processor(s) 401 by holding recently accessed data, and data near recently accessed data, from memory 402.

Program instructions and data (e.g., software and data ×10) used to practice embodiments of the present invention may be stored in persistent storage 405 and in memory 402 for execution by one or more of the respective processor(s) 401 via cache 403. In an embodiment, persistent storage 405 includes a magnetic hard disk drive. Alternatively, or in addition to a magnetic hard disk drive, persistent storage 405 can include a solid state hard drive, a semiconductor storage device, a read-only memory (ROM), an erasable programmable read-only memory (EPROM), a flash memory, or any other computer readable storage media that is capable of storing program instructions or digital information.

The media used by persistent storage 405 may also be removable. For example, a removable hard drive may be used for persistent storage 405. Other examples include optical and magnetic disks, thumb drives, and smart cards that are inserted into a drive for transfer onto another computer readable storage medium that is also part of persistent storage 405. Process 220 can be stored in persistent storage 405 for access and/or execution by one or more of the respective processor(s) 401 via cache 403.

Communications unit 407, in these examples, provides for communications with other data processing systems or devices. In these examples, communications unit 407 includes one or more network interface cards. Communications unit 407 may provide communications through the use of either or both physical and wireless communications links. Program instructions and data (e.g., process 220) used to practice embodiments of the present invention may be downloaded to persistent storage 405 through communications unit 407.

I/O interface(s) 406 allows for input and output of data with other devices that may be connected to each computer system. For example, I/O interface(s) 406 may provide a connection to external device(s) 408, such as a keyboard, a keypad, a touch screen, and/or some other suitable input device. External device(s) 408 can also include portable computer readable storage media, such as, for example, thumb drives, portable optical or magnetic disks, and memory cards. Program instructions and data (e.g., process 220) used to practice embodiments of the present invention can be stored on such portable computer readable storage media and can be loaded onto persistent storage 405 via I/O interface(s) 406. I/O interface(s) 406 also connect to display 409.

Display 409 provides a mechanism to display data to a user and may be, for example, a computer monitor.

The programs described herein are identified based upon the application for which they are implemented in a specific embodiment of the invention. However, it should be appreciated that any particular program nomenclature herein is used merely for convenience, and thus the invention should not be limited to use solely in any specific application identified and/or implied by such nomenclature.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A multi-bit semiconductor device, the multi-bit semiconductor device comprising:
a substrate comprising one or more transistors;
the one or more transistors comprises of one or more terminals, one or more source drain, one or more gates, one or more gate spacers, one or more channels and one or more channel layers; and
the one or more channel layers envelopes the one or more channels, wherein:
each of the one or more channel layers has a different thickness from each of the one or more channel layers;
the different thickness of each of the one more channel layers contributes to an overall voltage of the multi-bit semiconductor device; and
the one or more channel layers comprises of a fe (ferroelectric) material.

2. The multi-bit semiconductor device of claim 1, wherein the one or more channels comprises of layers of nanosheets or nanowires.

3. The multi-bit semiconductor device of claim 1, wherein fe material further comprises of HK (high k).

4. The multi-bit semiconductor device of claim 1, wherein the one or more channels layers comprises of a first channel layer, a second channel layer and a third channel layer.

5. The multi-bit semiconductor device of claim 4, wherein:
the first channel layer has a thickness equal to T3,
the second channel layer has a thickness equal T2+T3; and
the third channel layer has a thickness equal to T1+T2+T3.

6. The multi-bit semiconductor device of claim 1, wherein distance between each channel of the one or more channel is in a range of 30 nm to 50 nm.

7. The multi-bit semiconductor device of claim 2, wherein the nanowires or nanosheets has a thickness of 8 nm.

8. A method for creating a multi-bit semiconductor device, the method comprising:
forming one or more channels, one or more source/drain, one or more gates and one or more gate spacers on a substrate;
depositing a first fe (ferroelectric) layer on the one or more channels;
depositing a first OPL (organic planarization layer);
chamfering the first fe layer;
removing the first OPL;
depositing a second fe layer;
depositing a second OPL;
recessing the second OPL;
removing the second OPL;
depositing the third fe layer; and
filling one or more gates with a metal.

9. The method of claim 8, wherein the one or more channels further comprises of nanowires.

10. The method of claim 8, wherein the first fe layer, the second fe layer and the third fe layer is made from HK (high k) material.

11. The method of claim 8, wherein chamfering the first fe layer further comprises:
removing the first fe layer from the one or more channels except for bottom-most channel of the one or more channels.

12. The method of claim 8, wherein chamfering the second fe layer further comprises:
removing the second fe layer from top-most channel of the one or more channels.

13. The method of claim 8, wherein the metal is selected from a group comprising of WFM (work function metal) and W (Tungsten).

14. The method of claim 10, wherein the HK material is HfO₂ (hafnium dioxide).

15. A computer system for using a multi-bit semiconductor device, the computer system comprising:
one or more computer processors;
one or more computer readable storage media; and
program instructions stored on the one or more computer readable storage media for execution by at least one of the one or more computer processors, the program instructions comprising:
program instructions to form one or more channels, one or more source/drain, one or more gates and one or more gate spacers on a substrate;
program instructions to deposit a first fe (ferroelectric) layer on the one or more channels,
program instructions to deposit a first OPL (organic planarization layer);
program instructions to chamfer the first fe layer;
program instructions to remove the first OPL;
program instructions to deposit a second fe layer;
program instructions to deposit a second OPL:
program instructions to recess the second OPL;
program instructions to remove the second OPL;
program instructions to deposit the third fe layer; and
program instructions to fill one or more gates with a metal.

16. The computer system of claim 15, wherein the one or more channels further comprises of nanowires.

17. The computer system of claim 15, wherein the first fe layer, the second fe layer and the third fe layer is made from HK (high k) material.

18. The computer system of claim 15, wherein the metal is selected from a group comprising of WFM (work function metal) and W (Tungsten).

19. The computer system of claim 15, wherein the HK material is HfO₂ (hafnium dioxide).

20. The computer system of claim 15, wherein program instruction to chamfer the first fe layer further comprises:
program instructions to remove the first fe layer from the one or more channels except for bottom-most channel of the one or more channels.
